(19) United States
(12) Patent Application Publication
(10) Pub. No.: US 2020/0231610 A1
(43) Pub. Date: Jul. 23, 2020

(54) TIN COMPOUND, TIN PRECURSOR COMPOUND FOR FORMING A TIN-CONTAINING LAYER, AND METHODS OF FORMING A THIN LAYER USING THE SAME

(71) Applicant: SAMSUNG ELECTRONICS CO., LTD., Suwon-si (KR)

(72) Inventors: Seung-Min RYU, Hwaseong-si (KR); Myong Woon KIM, Daejeon (KR); Younsoo KIM, Yongin-si (KR); Sang Ick LEE, Daejeon (KR); Jaesoon LIM, Seoul (KR); Younjoung CHO, Hwaseong-si (KR); Jun Hee CHO, Daejeon (KR); Won Mook CHAE, Daejeon (KR)

(73) Assignees: SAMSUNG ELECTRONICS CO., LTD., Suwon-si (KR); DNF Co., Ltd., Daejeon (KR)

(21) Appl. No.: 16/554,926

(22) Filed: Aug. 29, 2019

(30) Foreign Application Priority Data
Jan. 23, 2019 (KR) 10-2019-0008714

(51) Int. Cl. C07F 7/22; C23C 16/40; C23C 16/448; H01L 21/02; H01L 21/285

(52) U.S. Cl. CPC C07F 7/2284; C23C 16/407; C23C 16/448; H01L 21/28556; H01L 21/02175; H01L 21/02205; H01L 21/02271

(57) ABSTRACT

A tin compound, a tin precursor compound for forming a tin-containing layer, and a method of forming a thin layer, the tin compound being represented by Formula 1:

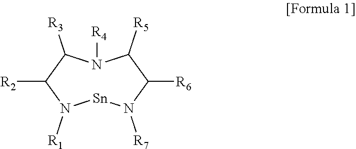

wherein R₁, R₂, R₃, R₄, R₅, R₆, and R₇ are each independently hydrogen, a linear alkyl group having 1 to 4 carbon atoms, or a branched alkyl group having 3 or 4 carbon atoms.

### CROSS-REFERENCE TO RELATED APPLICATIONS

Korean Patent Application No. 10-2019-0008714, filed on Jan. 23, 2019 in the Korean Intellectual Property Office, and entitled: “Tin Compound, Tin Precursor Compound for Forming a Tin-Containing Layer, and Methods of Forming a Thin Layer Using the Same,” is incorporated by reference herein in its entirety.

### BACKGROUND

### 1. Field

Embodiments relate to a tin compound, a tin precursor compound for forming a tin-containing layer, and a method of forming a thin layer using the tin precursor compound.

### 2. Description of the Related Art

According to the increase of speed and decrease of consumption power of electronic devices, a semiconductor device built therein may have a rapid operation speed and/or a low operation voltage. In order to satisfy such properties, semiconductor devices may be highly integrated, and patterns constituting a semiconductor device may be miniaturized.

### SUMMARY

The embodiments may be realized by providing a tin compound represented by Formula 1:

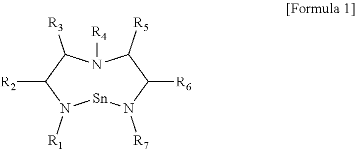

wherein R₁, R₂, R₃, R₄, R₅, R₆, and R₇ are each independently hydrogen, a linear alkyl group having 1 to 4 carbon atoms, or a branched alkyl group having 3 or 4 carbon atoms.

The embodiments may be realized by providing a tin precursor compound for forming a tin-containing layer, the compound being represented by Formula 1:

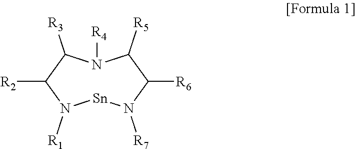

wherein R₁, R₂, R₃, R₄, R₅, R₆, and R₇ are each independently hydrogen, a linear alkyl group having 1 to 4 carbon atoms, or a branched alkyl group having 3 or 4 carbon atoms.

The embodiments may be realized by providing a method of forming a thin layer, the method including supplying a tin precursor compound represented by Formula 1; supplying a reaction source on a substrate; and forming a tin-containing layer on the substrate by reacting the tin precursor compound and the reaction source,

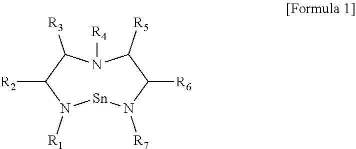

wherein R₁, R₂, R₃, R₄, R₅, R₆, and R₇ are each independently hydrogen, a linear alkyl group having 1 to 4 carbon atoms, or a branched alkyl group having 3 or 4 carbon atoms.

### BRIEF DESCRIPTION OF THE DRAWINGS

Features will be apparent to those of skill in the art by describing in detail exemplary embodiments with reference to the attached drawings in which:

FIG. 1 illustrates a flowchart of a method of forming a thin layer according to some exemplary embodiments;

FIG. 2 and FIG. 3 illustrate conceptual timing diagrams of methods of forming thin layers according to some exemplary embodiments, respectively;

FIG. 4A and FIG. 4B illustrate cross-sectional views of stages in methods of forming thin layers according to some exemplary embodiments;

FIG. 5 illustrates a flowchart of a method of forming a thin layer according to some exemplary embodiments;

FIG. 6 illustrates a graph showing thermogravimetric analysis (TGA) results of a tin compound synthesized according to a Synthetic Example;

FIG. 7 illustrates a graph showing differential scanning calorimetry (DSC) results of a tin compound synthesized according to the Synthetic Example;

FIG. 8 illustrates a graph showing a deposition thickness per cycle, of a tin oxide thin layer deposited according to Experimental Example 2, in accordance with a deposition temperature;

FIG. 9 illustrates a graph showing X-ray diffraction (XRD) analysis results of a tin oxide thin layer deposited according to Experimental Example 2;

FIG. 10 illustrates a conceptual diagram showing step coverage properties of a tin oxide thin layer deposited according to Experimental Example 2; and

FIG. 11 illustrates a graph showing a deposition thickness of a tin oxide thin layer per cycle deposited according to a Comparative Example in accordance with a deposition temperature.

### DETAILED DESCRIPTION

A tin compound according to an embodiment may be represented by Formula 1.

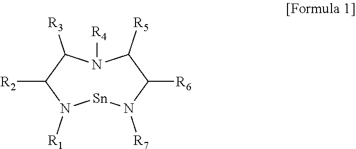

R₁, R₂, R₃, R₄, R₅, R₆, and R₇ may each independently be, e.g., hydrogen, a linear alkyl group having 1 to 4 carbon atoms, or a branched alkyl group having 1 to 4 carbon atoms (e.g., a branched alkyl group having 3 or 4 carbon atoms).

In an implementation, R₁ and R₇ may each independently be, e.g., hydrogen, methyl, ethyl, n-propyl, isopropyl, n-butyl, s-butyl, t-butyl, or isobutyl. In an implementation, R₁ and R₇ may be the same, e.g. R₁ and R₇ may both be one of hydrogen, methyl, ethyl, n-propyl, isopropyl, n-butyl, s-butyl, t-butyl, or isobutyl. In an implementation, R₁ and R₇ may be different from each other, e.g., R₁ and R₇ may independently be a different one of hydrogen, methyl, ethyl, n-propyl, isopropyl, n-butyl, s-butyl, t-butyl, or isobutyl.

In an implementation, R₂, R₃, R₅, and R₆ may each independently be, e.g., hydrogen, methyl, ethyl, n-propyl, isopropyl, n-butyl, s-butyl, t-butyl, or isobutyl. In an implementation, at least two among R₂, R₃, R₅, and R₆ may be the same. In an implementation, R₂ and R₃ may be the same, e.g., R₂ and R₃ may both be one of hydrogen, methyl, ethyl, n-propyl, isopropyl, n-butyl, s-butyl, t-butyl, and isobutyl. In an implementation, R₅ and R₆ may be the same, e.g., R₅ and R₆ may both be one of hydrogen, methyl, ethyl, n-propyl, isopropyl, n-butyl, s-butyl, t-butyl, or isobutyl. In an implementation, R₂ and R₆ may be the same, e.g., R₂ and R₆ may both be one of hydrogen, methyl, ethyl, n-propyl, isopropyl, n-butyl, s-butyl, t-butyl, or isobutyl. In an implementation. R₃ and R₅ may be the same, e.g. R₃ and R₅ may both be one of hydrogen, methyl, ethyl, n-propyl, isopropyl, n-butyl, s-butyl, t-butyl, or isobutyl. In an implementation, R₂, R₃, R₅, and R₆ may be the same, e.g., R₂, R₃, R₅, and R₆ may all be one of hydrogen, methyl, ethyl, n-propyl, isopropyl, n-butyl, s-butyl, t-butyl, or isobutyl.

In an implementation, R₄ may be, e.g., hydrogen, methyl, ethyl, n-propyl, isopropyl, n-butyl, s-butyl, t-butyl, or isobutyl.

In an implementation, the tin compound may be, e.g., a tin compound of Formula 2.

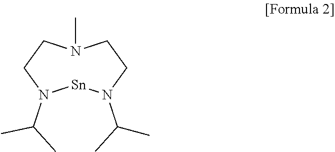

The tin compound according to an embodiment may be in a liquid state at room or ambient temperature and pressure (e.g., at about 1 atmosphere (atm) and about 15° C. to about 25° C., or about 20° C.). Accordingly, the storage and treatment of the tin compound may be easy.

Synthetic Method of Tin Compound

A method for synthesizing the tin compound of Formula 1 will be disclosed.

First, a salt compound may be synthesized according to Reaction X-1, and a starting material may be synthesized according to Reaction X-2.

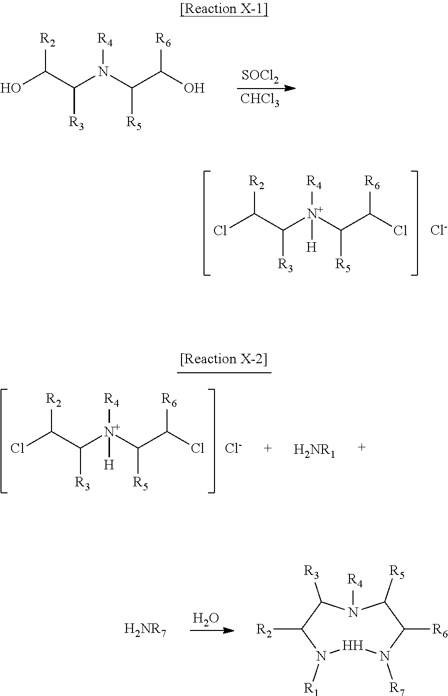

By reacting a n-butyllithium solution in hexane and the synthesized starting material (from Reaction X-2) according to Reaction 1, a lithium compound may be synthesized.

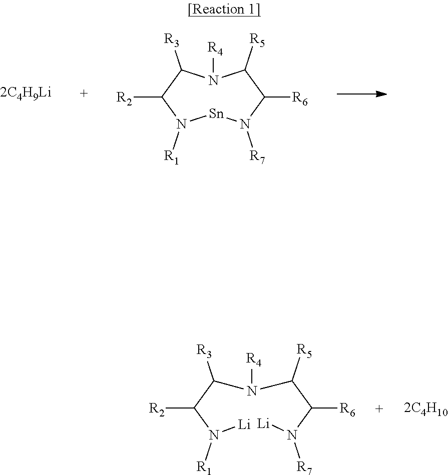

By reacting the lithium compound synthesized by Reaction 1 and a tin halide according to Reaction 2, a tin compound of Formula 1 may be synthesized.

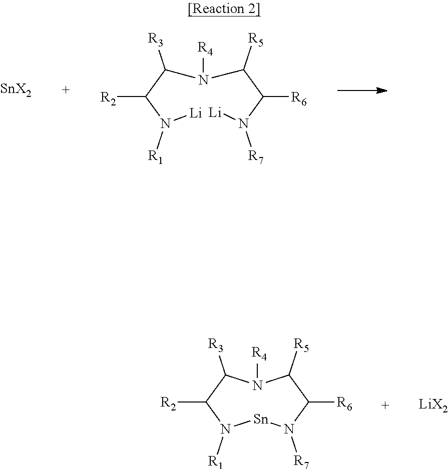

In an implementation, X may be, e.g., fluorine (F), chlorine (Cl), bromine (Br), or iodine (I).

### Synthetic Example: Synthesis of Tin Compound of Formula 2

100 g (0.84 mol) of CH₃N(C₂H₄OH)₂ and 500 ml of chloroform (CHCl₃) may be added to a 1,000 ml flask. At ambient temperature, 200 g (1.68 mol) of thionyl chloride (SOCl₂) may be slowly added, and materials in the flask may be stirred at about 25° C. for about 5 hours. As a result, 126 g of a salt compound may be produced according to Reaction Y-1.

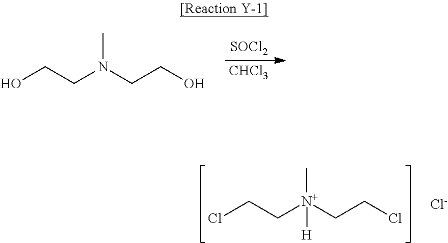

126 g (0.65 mol) of the salt compound produced in Reaction Y-1 and 235 ml of H₂O may be added to a 500 ml flask. At about 50° C., 116 g (1.96 mol) of isopropylamine (C₃H₉N) may be slowly added and materials in the flask may be stirred at about 50° C. for about 5 hours. As a result, 40 g of ((CH₃)₂CHNH(CH₂CH₂))₂NCH₃ may be produced according to Reaction Y-2.

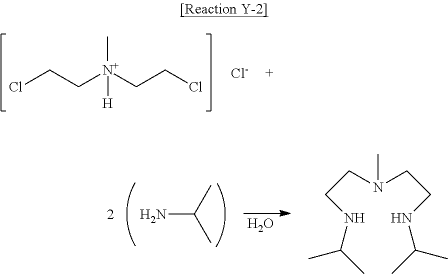

35 g (0.174 mol) of ((CH₃)₂CHNH(CH₂CH₂))₂NCH₃ and 100 ml of THF (Tetrahydrofuran) may be added to a 500 ml flask. At about −30° C., 147.8 ml (0.348 mol) of 2.353% n-butyllithium solution in hexane may be slowly added, and materials in the flask may be stirred at about 25° C. for about 5 hours. As a result, a lithium compound may be produced according to Reaction 3.

2C₄H₉Li+((CH₃)₂CHNH(CH₂CH₂))₂NCH₃→Li₂(((CH₃)₂CHN(CH₂CH₂))₂NCH₃)+2C₄H₁₀ [Reaction 3]

After producing the lithium compound, at about −70° C., 33 g (0.174 mol) of SnCl₂ and 100 ml of THF may be slowly added to the flask, and materials in the flask may be stirred at about 25° C. for about 6 hours. As a result, a tin compound of Formula 2 may be produced according to Reaction 4.

SnCl₂+Li₂(((CH₃)₂CHN(CH₂CH₂))₂NCH₃)→Sn(((CH₃)₂CHN(CH₂CH₂))₂NCH₃)+LiCl₂ [Reaction 4]

Through filtering and decreasing the pressure, solvents and by-products may be removed from the materials in the flask, and by separating the residual materials in the flask (at about 90° C. and about 0.16 torr), the tin compound of Formula 2 may be obtained.

The tin compound according to an embodiment may be used as a tin precursor compound for forming a tin-containing layer. In an implementation, the tin-containing layer may include, e.g., a metal layer including tin, a tin oxide layer, a tin nitride layer, a tin oxynitride layer, or a tin oxycarbonitride layer. In an implementation, the tin precursor compound may be used in an atomic layer deposition process or a chemical vapor deposition process for forming the tin-containing layer.

Hereinafter, a method of forming a thin layer (using the tin compound according to an embodiment as a tin precursor compound) will be disclosed.

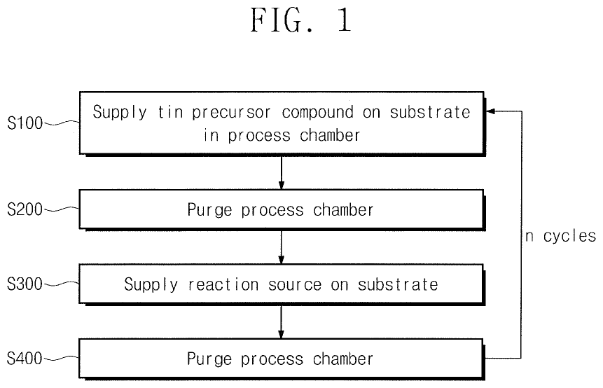

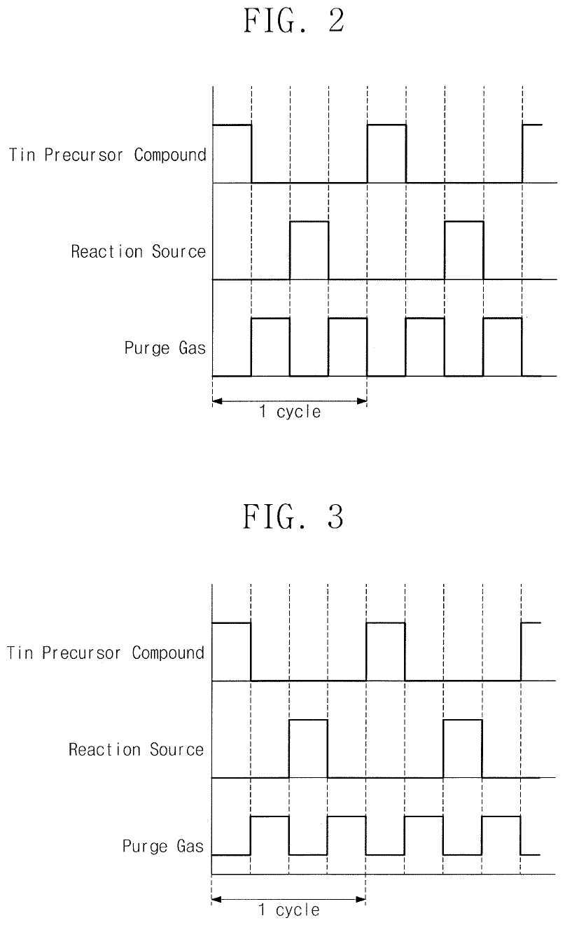

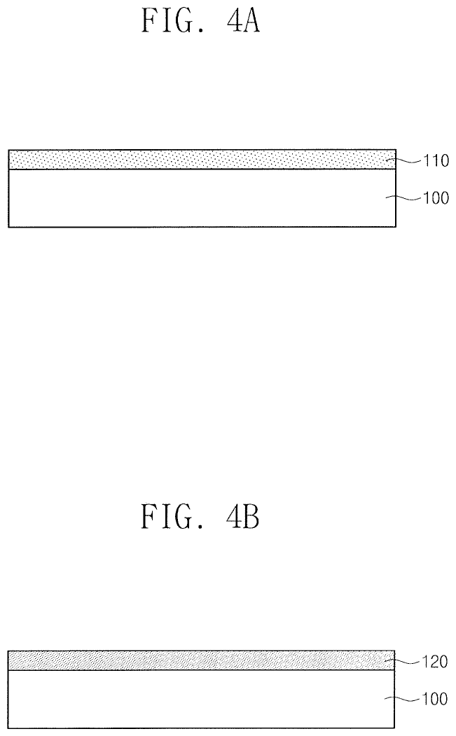

FIG. 1 illustrates a flowchart of a method of forming a thin layer according to some exemplary embodiments. FIG. 2 and FIG. 3 illustrate conceptual timing diagrams of methods of forming thin layers according to some exemplary embodiments, respectively. FIG. 4A and FIG. 4B illustrate cross-sectional views of stages of methods of forming thin layers according to some exemplary embodiments.

Referring to FIG. 1, FIG. 2 and FIG. 4A, a substrate 100 may be provided in a process chamber. On the substrate 100, a tin precursor compound of Formula 1 may be supplied (S100). The process chamber may be a chamber in which a deposition process for forming a thin layer is performed. The deposition process may be an atomic layer deposition process. The substrate 100 may include a semiconductor substrate, e.g., may include a semiconductor substrate and lower structures formed on the semiconductor substrate. The lower structures may include at least one insulating layer or at least one conductive layer.

The tin precursor compound may be supplied in a vaporized state on the substrate 100. The vaporized tin precursor compound may be chemisorbed on a surface of the substrate 100, and accordingly, a monolayer 110 of the tin precursor compound may be formed on the substrate 100.

By supplying a purge gas on the substrate 100, the process chamber may be purged (S200). The purge gas may include an inert gas such as argon (Ar), helium (He), and neon (Ne), or a nitrogen (N₂) gas. By supplying the purge gas, the tin precursor compound that is not adsorbed on the substrate 100 or physisorbed on the monolayer 110 may be removed from the process chamber. In an implementation, as shown in FIG. 2, after finishing the supplying of the tin precursor compound, the supplying of the purge gas may be initiated. In an implementation, referring to FIG. 3, the purge gas may be used as a carrier gas of the tin precursor compound. For example, during supplying the tin precursor compound, the purge gas may be supplied together therewith. In an implementation, the purge gas may be continuously supplied after finishing the supplying of the tin precursor compound. Accordingly, the process chamber may be purged.

Referring to FIG. 1, FIG. 2 and FIG. 4B, a reaction source may be supplied on the substrate 100 (S300). The reaction source may be supplied in a vaporized state on the substrate 100. The vaporized reaction source may react with the tin precursor compound of the monolayer 110, and accordingly, a tin-containing layer 120 may be formed on the substrate 100. In an implementation, the tin-containing layer 120 may be a tin oxide layer, and in this case, the reaction source may include, e.g., O₂, O₃, O radical, nitrogen dioxide, nitrogen monoxide, H₂O, hydrogen peroxide, formic acid, acetic acid, acetic anhydride, or a mixture thereof. In an implementation, the tin-containing layer 120 may be a tin nitride layer, and in this case, the reaction source may include, e.g., monoalkylamine, dialkylamine, trialkylamine, alkylenediamine, an organic amine compound, NH₃, NF₃, NO, N₂O, N radical, a hydrazine compound, or a mixture thereof. In an implementation, the tin-containing layer 120 may include carbon, and in this case, the reaction source may include a carbon source. The carbon source may include, e.g., hydrocarbon such as methane (CH₄), methanol (CH₃OH), carbon monoxide (CO), ethane (C₂H₆), ethylene (C₂H₄), ethanol (C₂H₅OH), acetylene (C₂H₂), acetone (CH₃COCH₃), propane (CH₃CH₂CH₃), propylene (C₃H₆), butane (C₄H₁₀), pentane (CH₃(CH₂)₃CH₃), pentene (C₅H₁₀), cyclopentadiene (C₅H₆), hexane (C₆H₁₄), cyclohexane (C₆H₁₂), benzene (C₆H₆), toluene (C₇H₈), or xylene (C₆H₄(CH₃)₂).

By supplying the purge gas on the substrate 100, the process chamber may be purged (S400). According to the supplying of the purge gas, unreacted reaction source and reaction by-products may be removed from the process chamber. In an implementation, as shown in FIG. 2, after finishing the supplying of the reaction source, the supplying of the purge gas may be initiated. In an implementation, referring to FIG. 3, the purge gas may be used as the carrier gas of the reaction source. For example, during the supplying of the reaction source, the purge gas may be supplied together therewith. The purge gas may be continuously supplied after finishing the supplying of the reaction source, and accordingly, the process chamber may be purged.

The stages (S100, S200, S300 and S400) together may constitute one cycle. The cycle may be repeated n times until the tin-containing layer 120 is formed to have a desired thickness (where n is an integer of 1 or more). For example, the stages (S100, S200, S300 and S400) may be performed sequentially and then the sequence may be repeated until the tin-containing layer 120 is formed to have a desired thickness.

In an implementation, the tin-containing layer 120 may be formed by the above-mentioned atomic layer deposition method. In this case, the temperature in the process chamber (e.g., the temperature of the substrate 100) may be kept at about 100° C. to about 600° C., and the pressure in the process chamber may be kept at about 10 Pa to about 1 atm.

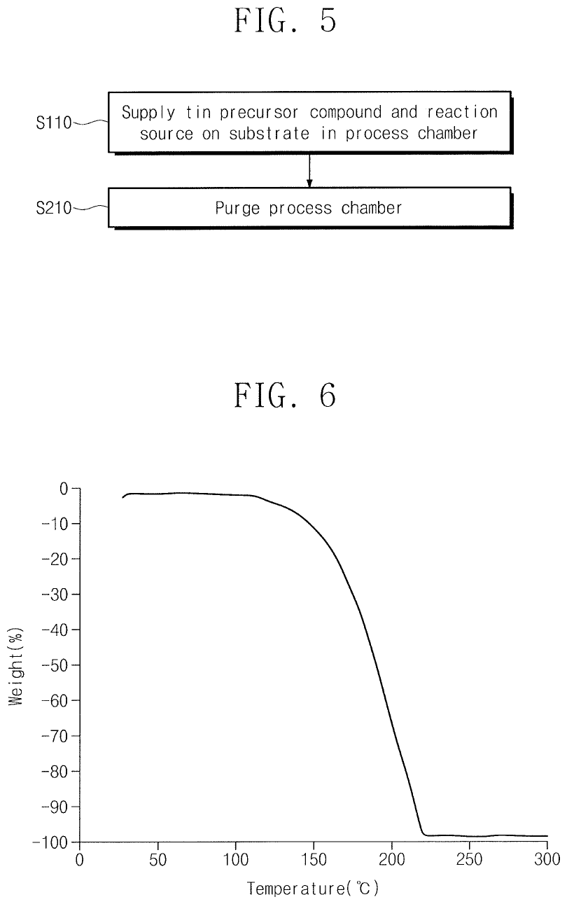

FIG. 5 illustrates a flowchart of a method of forming a thin layer according to some exemplary embodiments. For the brief explanation, different points from the method of forming a thin layer explained referring to FIG. 1 to FIG. 3, FIG. 4A and FIG. 4B will be mainly disclosed.

Referring to FIG. 5 and FIG. 4B, the substrate 100 may be provided in a process chamber. On the substrate 100, the tin precursor compound of Formula 1 and the reaction source may be supplied (S110). The process chamber may be a chamber for performing a deposition process for forming a thin layer therein. In an implementation, the deposition process may be a chemical vapor deposition process. The substrate 100 may include a semiconductor substrate, e.g., may include a semiconductor substrate and lower structures formed on the semiconductor substrate. The lower structures may include at least one insulating layer or at least one conductive layer.

The tin precursor compound and the reaction source may be supplied in a vaporized state on the substrate 100. In an implementation, the tin precursor compound and the reaction source may be independently vaporized and may be independently supplied on the substrate 100 (hereinafter, will be referred to as a single source method). In an implementation, the tin precursor compound and the reaction source may be pre-mixed in a desired composition, and the mixed raw material of the tin precursor compound and the reaction source may be vaporized and supplied on the substrate 100 (hereinafter, will be referred to as a cocktail source method). According to the reaction of the vaporized tin precursor compound and the vaporized reaction source and the chemisorption thereof on a surface of the substrate 100, the tin-containing layer 120 may be formed on the substrate 100. As explained referring to FIG. 1 to FIG. 3, FIG. 4A and FIG. 4B, the reaction source may be selected depending on the kind of the tin-containing layer 120.

By supplying the purge gas on the substrate 100, the process chamber may be purged (S210). According to the supplying of the purge gas, unreacted tin precursor compound, unreacted reaction source, and reaction by-products may be removed from the process chamber.

In an implementation, the tin-containing layer 120 may be formed by the above-mentioned chemical vapor deposition method. In this case, the temperature in the process chamber (e.g., the temperature of the substrate 100) may be kept at about 100° C. to about 1,000° C., and the pressure in the process chamber may be kept at about 10 Pa to about 1 atm.

Hereinafter, particular experimental examples and comparative examples will be provided for the clear understanding of the embodiments.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Experimental Example 1: Evaluation of Properties of Tin Compound of Formula 2

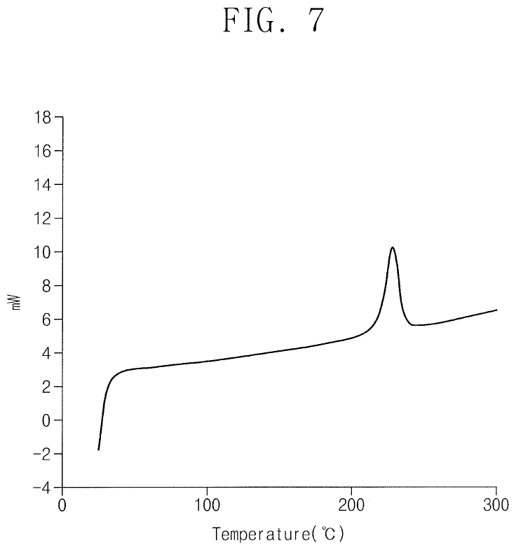

FIG. 6 illustrates a graph showing thermogravimetric analysis (TGA) results of a tin compound of Formula 2 synthesized according to the Synthetic Example, FIG. 7 illustrates a graph showing differential scanning calorimetry (DSC) results of the tin compound of Formula 2 synthesized according to the Synthetic Example.

Referring to FIG. 6, the tin compound of Formula 2 may have rapid vaporization properties in a range of about 150° C. to about 220° C. and about 99% or more thereof may be vaporized at about 220° C. Referring to FIG. 7, the tin compound of Formula 2 may be thermally stable at a temperature of about 210° C. or less. From the results of FIG. 6 and FIG. 7, it may be seen that the tin compound of Formula 2 may be used as a tin precursor compound in an atomic layer deposition process or a chemical vapor deposition process for manufacturing a semiconductor device.

### Experimental Example 2: Formation of Tin Oxide Layer Using Tin Compound of Formula 2 as Tin Precursor Compound

A tin oxide thin layer was formed on a silicon substrate by an atomic layer deposition method. The tin compound of Formula 2 was used as a tin precursor compound.

First, the silicon substrate was provided in a process chamber, and the temperature of the silicon substrate was kept at about 130° C. The tin compound of Formula 2 was filled in a first stainless steel bubbler container as a tin precursor compound and the temperature was kept at about 100° C. Deionized water (DI) was filled in a second stainless steel bubbler container as a reaction source and the temperature was kept at about 35° C. By heating the first bubbler container, the tin precursor compound was vaporized in the first bubbler container. By supplying the vaporized tin precursor compound on the silicon substrate using argon gas (25 sccm) as a carrier gas, the vaporized tin precursor compound was chemisorbed on a surface of the silicon substrate (S100 of FIG. 1). After that, by purging the process chamber using argon gas (3,000 sccm) for about 15 seconds, nonadsorbed tin precursor compound was removed from the process chamber (S200 of FIG. 1). By heating the second bubbler container, DI water was vaporized in the second bubbler container. By supplying the vaporized DI water on the silicon substrate using argon gas (50 sccm) as a carrier gas, the vaporized DI water was reacted with the adsorbed tin precursor compound. Accordingly, a tin oxide thin layer was formed on the silicon substrate (S300 of FIG. 1). Then, by purging the process chamber using argon gas (3,000 sccm) for about 30 seconds, unreacted materials and reaction by-products were removed from the process chamber (S400 of FIG. 1). The above-mentioned stages make up one cycle, and 1,000 cycles were performed. The temperature of the silicon substrate was changed from about 120° C. to about 200° C., and the stages at each temperature were performed for 1,000 cycles to form the tin oxide thin layer.

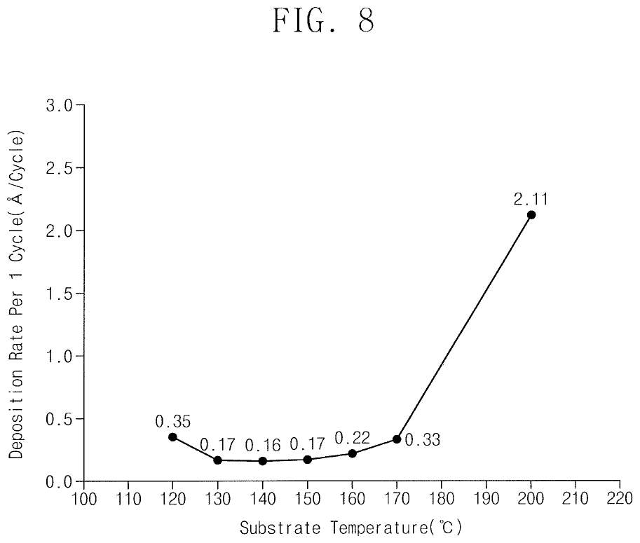

FIG. 8 illustrates a graph showing a deposition thickness per cycle, of a tin oxide thin layer deposited according to Experimental Example 2, in accordance with a deposition temperature. FIG. 8 shows results obtained by measuring the thickness of the tin oxide thin layer deposited according to Experimental Example 2 using a transmission electron microscope, and by showing a deposition thickness per 1 cycle in accordance with the temperature of a silicon substrate.

Referring to FIG. 8, it may be seen that where the temperature of the silicon substrate is changed from about 120° C. to about 170° C., the deposition thickness per 1 cycle is substantially constant. This shows that the tin oxide thin layer deposited by Experimental Example 2 in a temperature range of about 120° C. to about 170° C. was formed by atomic layer deposition mechanism. In addition, it may be seen that where the temperature of the silicon substrate is about 200° C., the deposition thickness per 1 cycle was markedly changed. This shows that the tin oxide thin layer deposited by Experimental Example 2 at a temperature of about 200° C. may be formed by another deposition mechanism other than an atomic layer deposition mechanism, e.g., a chemical vapor deposition mechanism. According to the results of FIG. 8, the tin compound of Formula 2 may be used as a tin precursor compound of an atomic layer deposition process when a temperature of the silicon substrate ranges from about 120° C. to about 170° C.

Table 1 shows the composition of the tin oxide thin layer deposited by Experimental Example 2. The composition of the tin oxide thin layer deposited on the silicon substrate which is in a temperature range of about 120° C. to about 150° C. was analyzed using X-ray photoelectron spectroscopy (XPS).

TABLE 1

| Substrate | | | | | | |
|---|---|---|---|---|---|---|
| temperature | Atomic content (%) | | | | | |
| (° C.) | O1s | Sn3d | C1s | Si2p | N1s | O/Sn |
| 120 | 49.7 | 50.3 | 0.0 | 0.0 | 0.0 | 0.99 |
| 130 | 49.1 | 50.9 | 0.0 | 0.0 | 0.0 | 0.97 |
| 140 | 49.7 | 50.3 | 0.0 | 0.0 | 0.0 | 0.99 |
| 150 | 49.4 | 50.5 | 0.0 | 0.0 | 0.0 | 0.98 |

Referring to Table 1, it may be seen that a SnO thin layer of which oxygen to tin ratio was about 1:1 was formed when a temperature of the silicon substrate ranges from about 120° C. to about 150° C. In addition, it may be seen that nitrogen and carbon impurities were not detected, and through this, a pure tin oxide thin layer in which impurities were not included was formed.

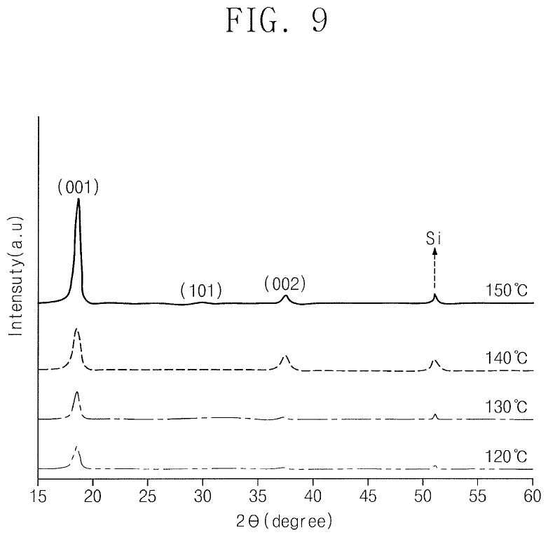

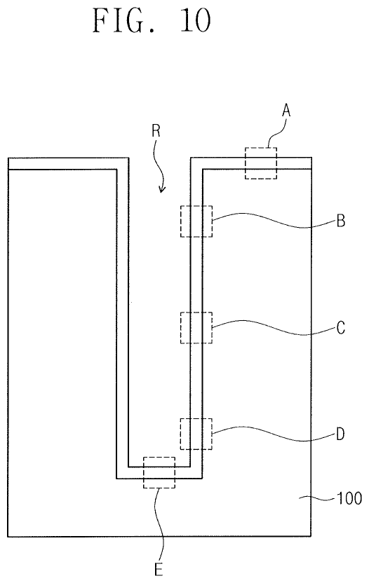

FIG. 9 illustrates a graph showing X-ray diffraction (XRD) analysis results of a thin layer deposited according to Experimental Example 2. FIG. 9 shows crystallinity of the tin oxide thin layer deposited on the silicon substrate which is in a temperature range of about 120° C. to about 150° C.

Referring to FIG. 9, it may be seen that the tin oxide thin layer deposited on the silicon substrate (which is in a temperature range of about 120° C. to about 150° C.) was a SnO thin layer having a tetragonal crystal structure. In addition, it may be seen that the crystallinity of the SnO thin layer increased according to the increase of the temperature of the silicon substrate.

FIG. 10 illustrates a conceptual diagram for explaining step coverage properties of a tin oxide thin layer deposited according to Experimental Example 2, and Table 2 shows a step coverage ratio of the tin oxide thin layer deposited according to Experimental Example 2.

Referring to FIG. 10, a substrate 100 including a recess R may be provided, and the aspect ratio of the recess R may be about 7:1. The tin oxide thin layer deposited according to Experimental Example 2 may be formed to fill the recess R. Table 2 shows the thicknesses of the tin oxide thin layer measured at positions A, B, C, D and E. In Table 2, the step coverage ratio represents a ratio of the thickness of the tin oxide thin layer at each position with respect to the thickness of the tin oxide thin layer at position A.

TABLE 2

| | Thickness of thin layer | Step coverage ratio |
|---|---|---|
| Analysis position | (Å) | (%) |
| A | 66 | — |
| B | 66 | 100 |
| C | 66 | 100 |
| D | 66 | 100 |
| E | 66 | 100 |

Referring to FIG. 10 and Table 2, it may be seen that the tin oxide thin layer formed in the recess R of which aspect ratio is about 7:1 was formed to substantially the same thickness on a bottom surface E of the recess R, on an inner sidewall B, C, and D of the recess R, and on a top surface A of the substrate 100. For example, it may be seen that a tin oxide thin layer having excellent step coverage properties was formed.

In an implementation, through the atomic layer deposition process using the tin precursor compound of Formula 2, the SnO thin layer having an oxygen to tin ratio of about 1:1 may be formed. The SnO thin layer may be used in, e.g., a dielectric layer of a DRAM cell capacitor, a gate electrode or a gate dielectric layer constituting a metal-oxide-semiconductor field-effect transistor (MOSFET), an electrode, or the like. The SnO thin layer may have a relatively large energy band gap, and leakage current of a semiconductor device including the SnO thin layer may decrease.

### Comparative Example: Formation of Tin Oxide Layer Using Tetravalent Tin Compound as Tin Precursor Compound

A tin oxide thin layer was formed on a silicon substrate by an atomic layer deposition method. Bis(1-dimethylamino-2-methyl-2-propoxy)tin, a tetravalent tin compound, was used as a tin precursor compound.

First, a silicon substrate was provided in a process chamber, and the temperature of the silicon substrate was kept at about 90° C. Bis(1-dimethylamino-2-methyl-2-propoxy)tin was filled as a tin precursor compound in a first stainless steel bubbler container, and the temperature was kept at about 70° C. DI water was filled in a second stainless steel bubbler container as a reaction source and the temperature was kept at about 35° C. By heating the first bubbler container, the tin precursor compound was vaporized in the first bubbler container. By supplying the vaporized tin precursor compound on the silicon substrate using argon gas (100 sccm) as a carrier gas, the vaporized tin precursor compound was chemisorbed on a surface of the silicon substrate. After that, by purging the process chamber using argon gas (3,000 sccm) for about 10 seconds, non-adsorbed tin precursor compound was removed from the process chamber. By heating the second bubbler container, DI water was vaporized in the second bubbler container. By supplying the vaporized DI water on the silicon substrate using argon gas (50 sccm) as a carrier gas, the vaporized DI water was reacted with the adsorbed tin precursor compound. Accordingly, a tin oxide thin layer was formed on the silicon substrate. Then, by purging the process chamber for about 10 seconds using argon gas (3,000 sccm), unreacted materials and reaction by-products were removed from the process chamber. The above-mentioned stages constitute one cycle, and 300 cycles were performed. The temperature of the silicon substrate was changed from about 90° C. to about 210° C., and the stages at each temperature were performed for 300 cycles to form the tin oxide thin layer.

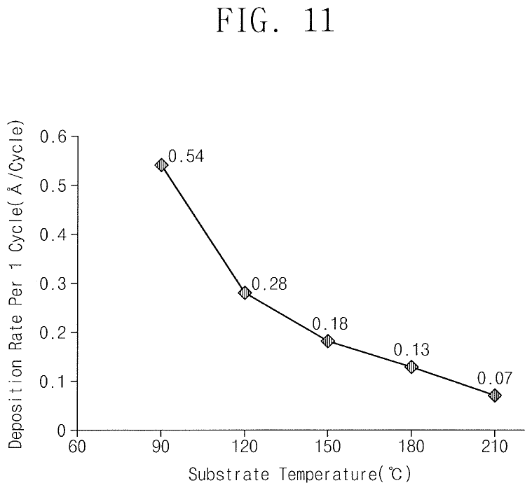

FIG. 11 illustrates a graph showing a deposition thickness per cycle, of a thin layer deposited according to the Comparative Example, in accordance with a deposition temperature. FIG. 11 shows results obtained by measuring the thickness of the thin layer deposited according to the Comparative Example using a transmission electron microscope and by showing the deposition thickness per 1 cycle in accordance with the temperature of a silicon substrate.

Referring to FIG. 11, it may be seen that the deposition thickness per 1 cycle was markedly changed by varying the temperature of the silicon substrate from about 90° C. to about 210° C. For example, the tin oxide thin layer deposited by the Comparative Example was formed by another deposition mechanism (other than an atomic layer deposition mechanism, e.g., chemical vapor deposition mechanism). For example, a temperature range in which deposition by atomic layer deposition mechanism is possible was not present for bis(1-dimethylamino-2-methyl-2-propoxy)tin, and accordingly, bis(1-dimethylamino-2-methyl-2-propoxy)tin may be inappropriate as the tin precursor compound for atomic layer deposition.

By way of summation and review, development of a deposition process for forming a thin layer having a uniform thickness and a desired composition in a miniaturized three-dimensional structure has been considered, and a raw material compound may be used for the deposition process for forming the thin layer.

According to one or more embodiments, a tin compound of Formula 1 may be provided, and the tin compound of Formula 1 may be used as a tin precursor compound of an atomic layer deposition process or a chemical vapor deposition process for forming a tin-containing layer. The tin compound of Formula 1 may be present in a liquid state at ambient temperature and pressure, and may have rapid vaporization properties and excellent thermal stability. Accordingly, the tin compound of Formula 1 may be readily used as the tin precursor compound of an atomic layer deposition process or a chemical vapor deposition process. When the tin compound of Formula 1 is used in an atomic layer deposition process, a tin-containing layer having excellent step coverage properties may be formed. For example, a SnO thin layer having an oxygen to tin ratio of about 1:1 may be formed.

According to one or more embodiments, a tin compound may be provided. A tin precursor compound for forming a tin-containing layer may be provided, and a method of forming a thin layer using the novel tin precursor compound may be provided.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A tin compound represented by Formula 1: 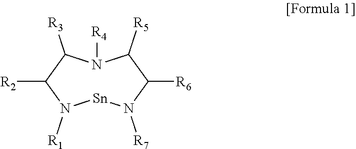
wherein R₁, R₂, R₃, R₄, R₅, R₆, and R₇ are each independently hydrogen, a linear alkyl group having 1 to 4 carbon atoms, or a branched alkyl group having 3 or 4 carbon atoms.

2. The tin compound as claimed in claim 1, wherein:
R₁ and R₇ are the same, and
R₁ and R₇ are hydrogen, methyl, ethyl, n-propyl, isopropyl, n-butyl, s-butyl, t-butyl, or isobutyl.

3. The tin compound as claimed in claim 1, wherein:
R₂ and R₆ are the same, and
R₂ and R₆ are hydrogen, methyl, ethyl, n-propyl, isopropyl, n-butyl, s-butyl, t-butyl, or isobutyl.

4. The tin compound as claimed in claim 1, wherein:
R₃ and R₅ are the same, and
R₃ and R₅ are hydrogen, methyl, ethyl, n-propyl, isopropyl, n-butyl, s-butyl, t-butyl, or isobutyl.

5. The tin compound as claimed in claim 1, wherein:
R₂ and R₃ are the same, and
R₂ and R₃ are hydrogen, methyl, ethyl, n-propyl, isopropyl, n-butyl, s-butyl, t-butyl, or isobutyl.

6. The tin compound as claimed in claim 1, wherein:
R₅ and R₆ are the same, and
R₅ and R₆ are hydrogen, methyl, ethyl, n-propyl, isopropyl, n-butyl, s-butyl, t-butyl, and isobutyl.

7. The tin compound as claimed in claim 1, wherein:
R₂, R₃, R₅, and R₆ are the same, and
R₂, R₃, R₅, and R₆ are hydrogen, methyl, ethyl, n-propyl, isopropyl, n-butyl, s-butyl, t-butyl, and isobutyl.

8. (canceled)

9. A tin precursor compound for forming a tin-containing layer, the compound being represented by Formula 1: 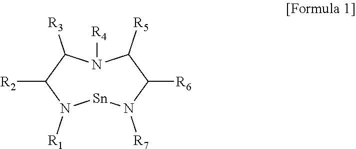
wherein R₁, R₂, R₃, R₄, R₅, R₆, and R₇ are each independently hydrogen, a linear alkyl group having 1 to 4 carbon atoms, or a branched alkyl group having 3 or 4 carbon atoms.

10. The tin precursor compound as claimed in claim 9, wherein:
R₁ and R₇ are the same, and
R₁ and R₇ are hydrogen, methyl, ethyl, n-propyl, isopropyl, n-butyl, s-butyl, t-butyl, or isobutyl.

11. The tin precursor compound as claimed in claim 9, wherein:
at least two of R₂, R₃, R₅, and R₆ are the same, and
the at least two of R₂, R₃, R₅, and R₆ are hydrogen, methyl, ethyl, n-propyl, isopropyl, n-butyl, s-butyl, t-butyl, and isobutyl.

12. The tin precursor compound as claimed in claim 11, wherein R₂ and R₃ are the same.

13. The tin precursor compound as claimed in claim 12, wherein R₅ and R₆ are the same.

14. The tin precursor compound as claimed in claim 13, wherein R₂, R₃, R₅, and R₆ are hydrogen.

15. The tin precursor compound as claimed in claim 11, wherein R₂ and R₆ are the same.

16. The tin precursor compound as claimed in claim 11, wherein R₃ and R₅ are the same.

17. The tin precursor compound as claimed in claim 11, wherein R₄ is hydrogen, methyl, ethyl, n-propyl, isopropyl, n-butyl, s-butyl, t-butyl, or isobutyl.

18.-20. (canceled)

21. A method of forming a thin layer, the method comprising:
supplying a tin precursor compound represented by Formula 1;
supplying a reaction source on a substrate; and
forming a tin-containing layer on the substrate by reacting the tin precursor compound and the reaction source, 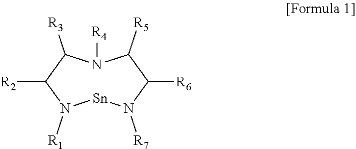
wherein R₁, R₂, R₃, R₄, R₅, R₆, and R₇ are each independently hydrogen, a linear alkyl group having 1 to 4 carbon atoms, or a branched alkyl group having 3 or 4 carbon atoms.

22. The method of forming a thin layer as claimed in claim 21, wherein:
the reaction source is O₂, O₃, O radical, nitrogen dioxide, nitrogen monoxide, H₂O, hydrogen peroxide, formic acid, acetic acid, acetic anhydride, or a mixture thereof, and
the tin-containing layer is a tin oxide layer.

23. The method of forming a thin layer as claimed in claim 22, wherein:
the tin-containing layer includes SnO, and
an atomic ratio of Sn to 0 in the tin-containing layer is 1:1.

24. The method of forming a thin layer as claimed in claim 21, wherein:
the reaction source is monoalkylamine, dialkylamine, trialkylamine, alkylenediamine, an organic amine compound, NH₃, NF₃, NO, N₂O, N radical, a hydrazine compound, or a mixture thereof, and
the tin-containing layer is a tin nitride layer.

25. (canceled)
